(19) United States
(12) Patent Application Publication
(10) Pub. No.: US 2026/0247869 A1
(43) Pub. Date: Aug. 20, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Huachun LIU, Hsinchu (TW); Shao-Ling CHANG, Hsinchu City (TW); Min-Yung KO, Hsinchu City (TW); Fu-Ting SUNG, Yangmei City (TW)

(21) Appl. No.: 19/054,375

(22) Filed: Feb. 14, 2025

(51) Int. Cl. H10N 50/10; G11C 11/16; H10N 50/01; H10N 50/85

(52) U.S. Cl. CPC H10N 50/10; H10N 50/01; H10N 50/85; G11C 11/161

(57) ABSTRACT

A hardmask structure including two dielectric layers is used as a mask to pattern a magnetic tunnel junction (MTJ) structure and a bottom electrode layer of a memory device. The dual dielectric hardmask structure is removed in a halogen-based etch process, and a top metal layer of the MTJ structure, which is resistant to halogen-based etchants, is used as the top electrode of the memory device. The dual dielectric layer hardmask structure has a lower height than a dielectric and metal layer hardmask structure where the metal layer is formed into a top electrode, resulting in a lower aspect ratio than the dielectric and metal layer hardmask structure. Due to the lower aspect ratio and non-metal composition of the dual dielectric layer hardmask structure, generation of metal by-products during patterning of the MTJ and bottom electrode layers may be reduced and/or prevented, thereby preventing shorts between memory device electrodes.

### BACKGROUND

A semiconductor device may include a non-volatile memory, which is able to store data in the absence of power. Non-volatile memory technologies include magneto-resistive random-access memory (MRAM), phase change random access memory (PC-RAM), and resistive random access memory (RRAM), among other examples. These non-volatile memory technologies are compatible with complementary metal-oxide-semiconductor (CMOS) logic fabrication processes, which enables logic and memory circuitry to be integrated onto the same semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example semiconductor device including an example semiconductor memory structure described herein.

FIGS. 2A-2E are diagrams of an example implementation of forming a semiconductor device described herein.

FIGS. 3A-3J are diagrams of an example implementation of forming a semiconductor memory structure described herein.

FIG. 4 is a flowchart of an example process associated with forming a magnetic tunnel junction.

FIG. 5 is a flowchart of an example process associated with forming a magnetic tunnel junction.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A memory cell (e.g., an MRAM cell) may include a memory device including a magnetic tunnel junction (MTJ) structure arranged vertically between a bottom electrode and a top electrode. To form the memory device, a semiconductor stack may be deposited over a substrate, where the semiconductor stack includes a bottom electrode layer, MTJ layers disposed on the bottom electrode layer, and a hardmask (HM) structure disposed on the MTJ layers. The HM structure may include, for example, a dielectric layer on a metal layer, where the metal layer is patterned into a top electrode. Using the dielectric layer as a mask, a first etch operation may be performed to pattern the metal layer into a top electrode. Then, using the top electrode as a mask, a second etch operation may be performed to pattern the MTJ layers and the bottom electrode layer into an MTJ structure and a bottom electrode. The first and/or second etch operations may include an ion beam etching (IBE) process in which beams of charged particles (e.g., argon (Ar)ions) are directed to a substrate that is to be etched. When an IBE process is used to pattern the metal layer (e.g., titanium nitride (TiN)) into the top electrode, metal by-products (e.g., portions of the metal layer) may be produced.

In some cases, the dimensions of the HM structure result in a high aspect ratio (e.g., a relatively large height (vertical dimension) to width (horizontal dimension) ratio) of the HM structure. In addition, the metal layer of the HM structure may have a greater vertical dimension than a vertical dimension of the dielectric layer of the HM structure. Given a low pitch between adjacent HM structures used to form adjacent memory devices, and a relatively large height of the metal layers, metal by-products from an IBE process to pattern a metal layer into a top electrode may attach to sides of metal layers of adjacent HM structures. These metal by-products may result in shorts between electrodes of adjacent memory structures and/or between top and bottom electrodes of the same memory structure, which may reduce performance and/or result in device malfunction.

In some implementations, an HM structure includes two dielectric layers, where the dual dielectric layer HM structure is used as a mask to pattern an MTJ structure of a memory device (e.g., an MRAM device), and to pattern a bottom electrode layer of the memory device. The dual dielectric layer HM structure is removed in a halogen-based etch process, and a top metal layer of the MTJ structure is used as the top electrode of the memory device. The top metal layer of the MTJ structure may be formed from a material that is resistant to halogen-based etchants. The dual dielectric layer HM structure has a lower height than a dielectric and metal layer HM structure where the metal layer is formed into a top electrode, resulting in a lower aspect ratio (e.g., height-to-width ratio) than the dielectric and metal layer HM structure. Due to the lower aspect ratio and the non-metal composition of the dual dielectric layer HM structure, generation of metal by-products during patterning of the MTJ and bottom electrode layers is reduced and/or prevented, thereby preventing shorts between electrodes of adjacent memory devices and/or between top and bottom electrodes of the same memory device. As a result, memory device performance may be increased and malfunction incidents may be decreased.

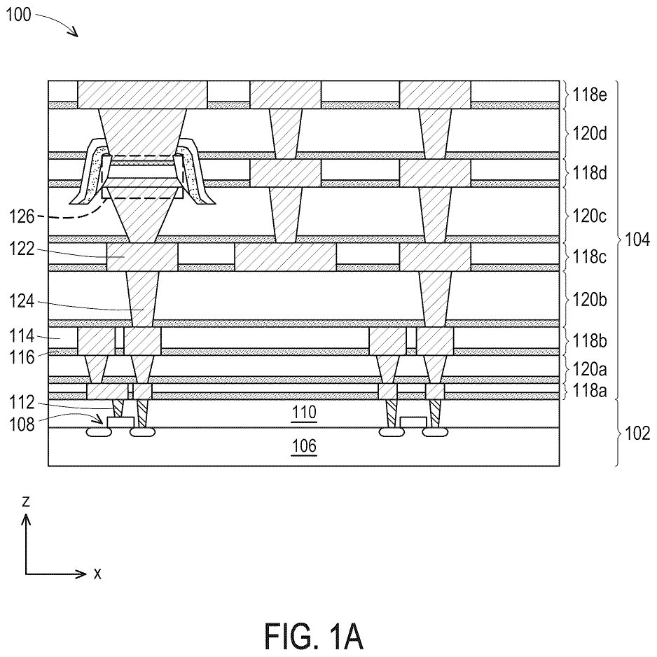

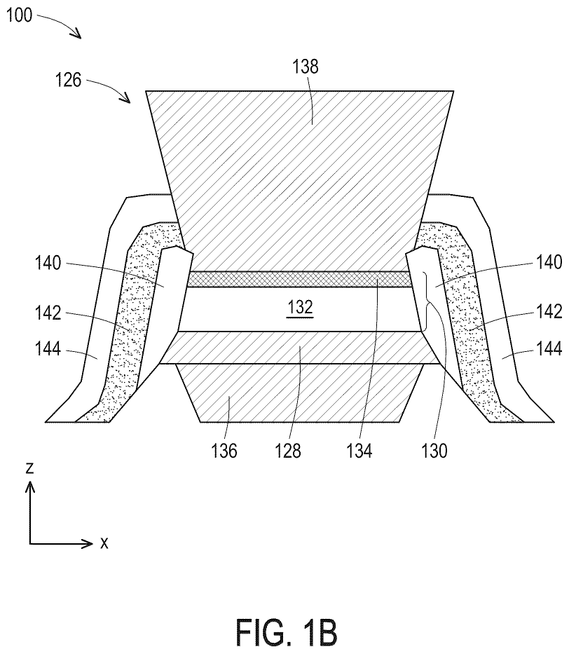

FIGS. 1A and 1B are diagrams of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1A illustrates a cross-section view of the semiconductor device 100. As shown in FIG. 1A, the semiconductor device 100 may include a device layer 102 and an interconnect layer 104 arranged in a z-direction in the semiconductor device 100 with respect to the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC). Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118e that are vertically arranged and alternate with a plurality of layers 120a-120d in the z-direction (e.g., vertically alternate). The layers 118a-118e each include a layer of metallization structures 122, and the layers 120a-120d each include a layer of interconnect structures 124.

The layers 118a-118e of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO” layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1A, a memory device 126 is included in the interconnect layer 104 of the semiconductor device 100. The memory device 126 may be a semiconductor structure that extends through and/or is included in one or more dielectric layers in the interconnect layer 104, such as one or more ILD layers 114 and/or one or more ESLs 116. In some implementations, an integrated circuit device 108 is electrically coupled to a memory device 126 to form a memory cell (e.g., an MRAM cell or another type of resistance-based memory cell) in the semiconductor device 100. In some implementations, a memory device 126 is a non-volatile memory device configured to store data in the absence of power. In some implementations, a memory device 126 is configured to perform another function in the semiconductor device 100.

FIG. 1B is a diagram of a portion of the semiconductor device 100 including the memory device 126. As shown in FIG. 1B, the memory device 126 includes a stacked semiconductor structure with a bottom electrode layer 128 and an MTJ structure 130 including a plurality of underlying layers 132 and a top layer 134 (e.g., cap layer). The underlying layers 132 may include a fixed layer and a free layer (e.g., ferromagnetic layers), separated by a tunnel barrier layer, that selectively allow quantum tunneling of electrons. The free and fixed layers may include ferrous materials including a combination of iron (Fe) and one or more of cobalt (Co), boron (B), and/or nickel (Ni), among other examples, and the tunnel barrier layer may include a crystalline material, such as magnesium oxide (MgO) and/or another suitable material. In operation, a magnetic direction associated with the free layer may be aligned in parallel with a magnetic direction associated with the fixed layer to place the MTJ structure 130 into an ON or 1 state, in which quantum tunneling is allowed, and the MTJ structure 130 exhibits a lower resistance. On other hand, the magnetic direction associated with the free layer may be reversed (that is, anti-parallel) relative to the magnetic direction associated with the fixed layer, to place the MTJ structure 130 into an OFF or 0 state, in which quantum tunneling is disallowed, and the MTJ structure 130 exhibits a higher resistance.

The top layer 134, which is a top electrode of the memory device 126, includes one or more electrically conductive materials. The material(s) of the top layer 134 also exhibit relatively high etch resistivity to halogen-based (e.g., fluorine-based, chlorine-based) etchants so that other materials may be selectively etched with respect to the top layer 134, and/or the top layer 134 may function as an ESL when a halogen-based etchant is used. The relatively high etch resistivity to halogen-based etchants prevents etching damage to the underlying layers 132. Examples of the electrically conductive material of the top layer include metals such as ruthenium (Ru), platinum (Pt), gold (Au), nickel (Ni), or chromium (Cr), among other examples.

The bottom electrode layer 128 is a bottom electrode of the memory device 126, and may include one or more electrically conductive materials. Examples include metals such as molybdenum (Mo), nickel (Ni), iridium (Ir), and chromium (Cr), as well as metal nitrides such as titanium nitride (TiN) or tantalum nitride (TaN), among other examples.

The memory device 126 may be electrically coupled and/or physically coupled to a bottom interconnect structure 136 (e.g., via) and to a top interconnect structure 138 (e.g., via). The top interconnect structure 138 and the bottom interconnect structure 136 may each include one or more conductive structures in the interconnect layer 104, such as one or more interconnect structures 124, among other examples. The top interconnect structure 138 and the bottom interconnect structure 136 may each be formed in and/or through one or more of the ILD layers 114 and/or ESLs 116.

In some implementations, the bottom interconnect structure 136 is disposed under the bottom electrode layer 128 in the z-direction, and is in direct physical contact with a bottom surface of the bottom electrode layer 128. In some implementations, the top interconnect structure 138 is disposed over the top layer 134 (e.g., top electrode) in the z-direction, and is in direct physical contact with a top surface of the top layer 134.

First spacer layers 140 are disposed on and along side surfaces of the bottom electrode layer 128, the MTJ structure 130 including the underlying layers 132 and the top layer 134, and on a lower portion of the top interconnect structure 138. As shown in FIG. 1B, the first spacer layers 140 may extend below a bottom edge of the bottom electrode layer 128. The first spacer layers 140 may be in direct physical contact with side surfaces of the bottom electrode layer 128, the MTJ structure 130 including the underlying layers 132 and the top layer 134, and the lower portion of the top interconnect structure 138. The first spacer layers 140 may include a dielectric material such as a nitride (e.g., a silicon nitride (SiₓN_{y}) and/or another nitride material), and/or another suitable material. The first spacer layers 140 may protect the MTJ structure 130 from moisture.

Second spacer layers 142 are disposed on side surfaces of the first spacer layers 140, on parts of top surfaces of the first spacer layers 140, and on portions of side surfaces of the top interconnect structure 138. As shown in FIG. 1B, the second spacer layers 142 may extend below a bottom edge of the bottom electrode layer 128 and/or below bottom edges of the first spacer layers 140. The second spacer layers 142 may be in direct physical contact with the side surfaces of the first spacer layers 140, the parts of the top surfaces of the first spacer layers 140, and the portions of the side surfaces of the top interconnect structure 138. The second spacer layers 142 may include a dielectric material such as an oxide (e.g., a silicon oxide (SiOₓ) and/or another oxide material), and/or another suitable material.

Third spacer layers 144 are disposed on side surfaces of the second spacer layers 142, on top surfaces of the second spacer layers 142, and on portions of side surfaces of the top interconnect structure 138. As shown in FIG. 1B, the third spacer layers 144 may extend below a bottom edge of the bottom electrode layer 128 and/or below bottom edges of the first spacer layers 140. The third spacer layers 144 may be in direct physical contact with the side surfaces of the second spacer layers 142, the top surfaces of the second spacer layers 142, and the portions of the side surfaces of the top interconnect structure 138. The second spacer layers 142 are interposed between the first spacer layers 140 and the third spacer layers 144. The third spacer layers 144 may include a dielectric material such as an oxide (e.g., an aluminum oxide (AlₓO_{y}) and/or another oxide material), and/or another suitable material. The third spacer layers 144 may protect the MTJ structure 130 and other layers under the third spacer layers 144 from chemical damage. The second spacer layers 142 may function as adhesion layers between the first spacer layers 140 and the third spacer layers 144.

As indicated above, FIGS. 1A and 1B are provided as examples. Other examples may differ from what is described with regard to FIGS. 1A and 1B.

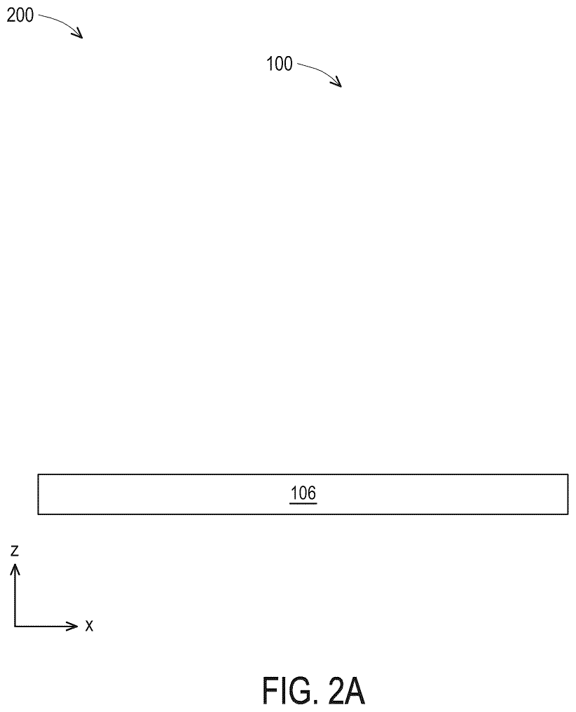

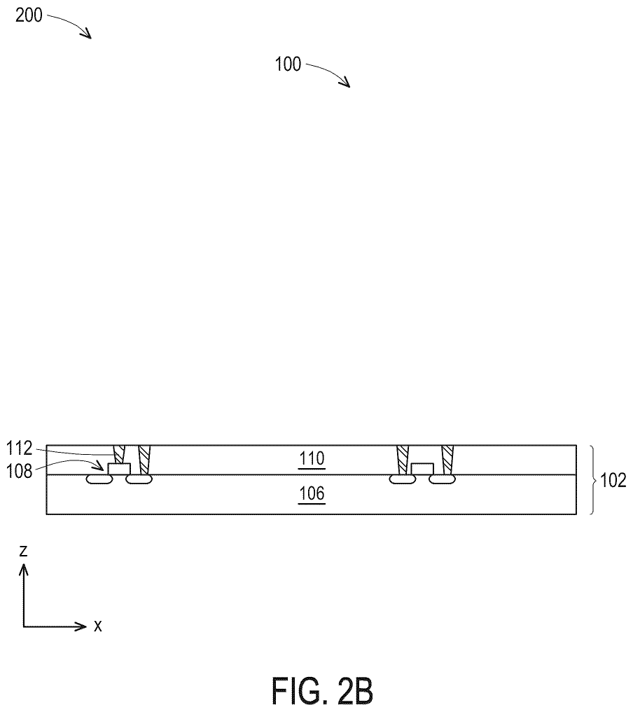

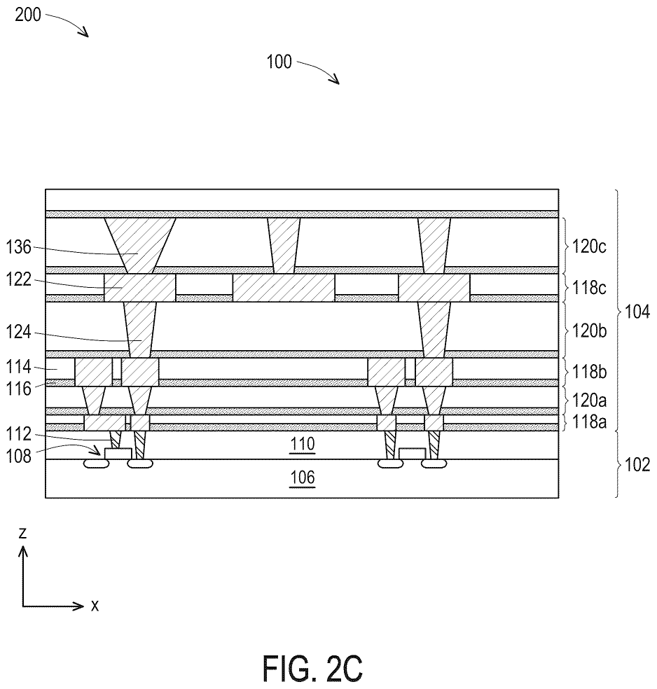

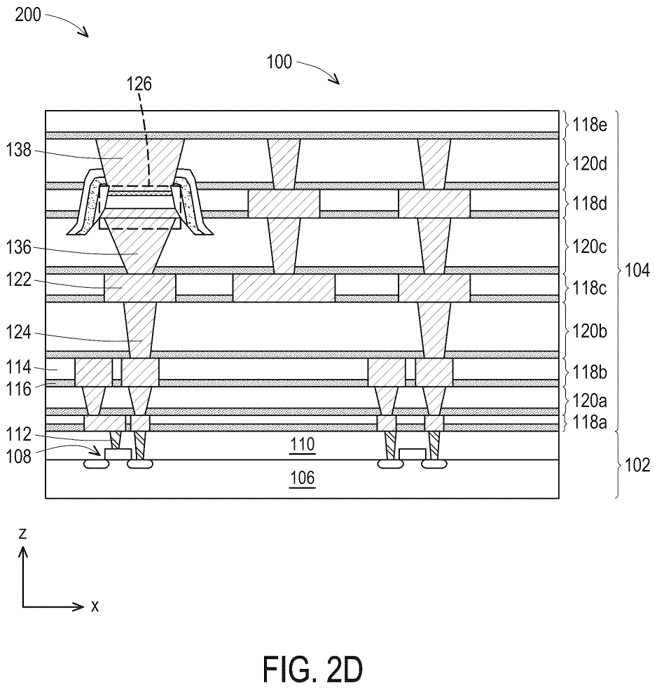

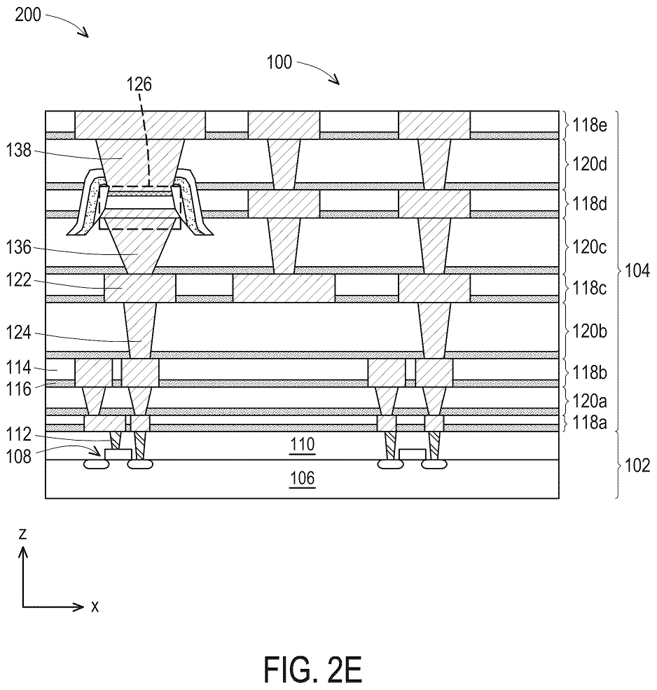

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 2C, a deposition tool, an exposure tool, a developer tool, an etch tool, a planarization tool, a plating tool, and/or another semiconductor processing tool may be used to perform various operations to form the metallization structures 122 and to form the interconnect structures 124, including bottom interconnect structure 136, in the first portion of the interconnect layer 104 of the semiconductor device 100.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b, 118c, 118d, 118e, 120b, 120c, and 120d may be formed in a similar manner.

One or more deposition tools may be used to deposit the metallization structures 122 and/or the interconnect structures 124 using a PVD technique, an ALD technique, a CVD technique, an electroplating technique (e.g., an electro-chemical plating technique), and/or another suitable deposition technique. In some implementations, a planarization tool may be used to planarize the metallization structures 122 and/or the interconnect structures 124 after the metallization structures 122 and/or the interconnect structures 124 are deposited.

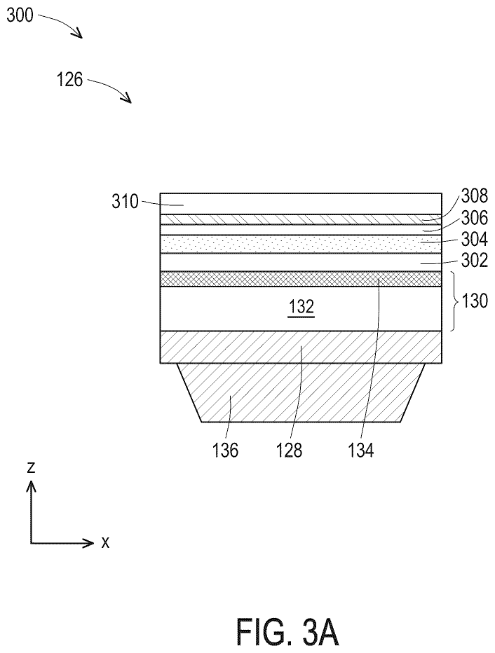

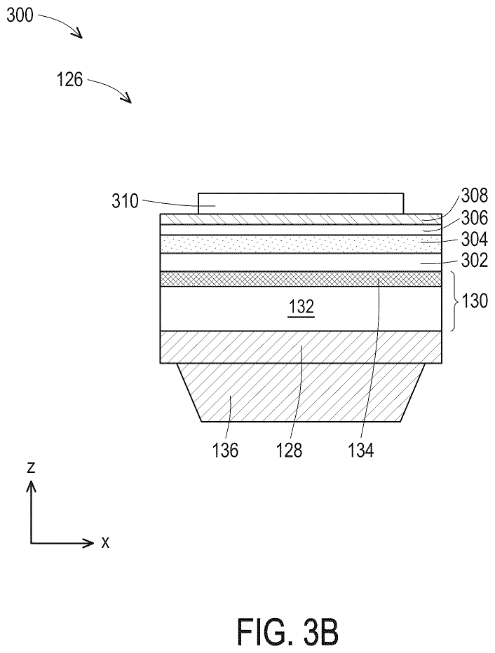

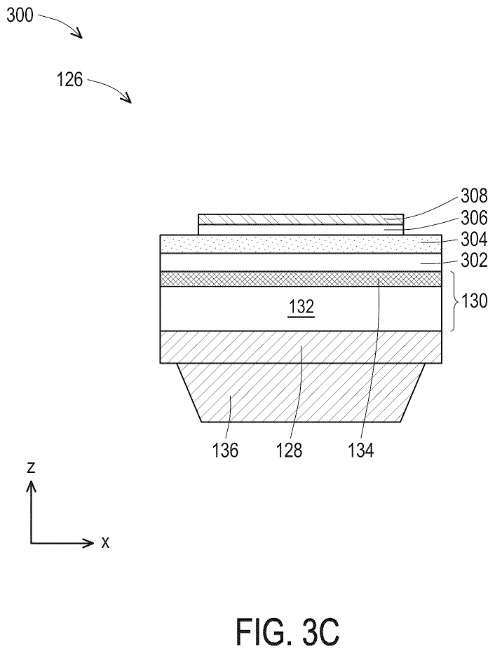

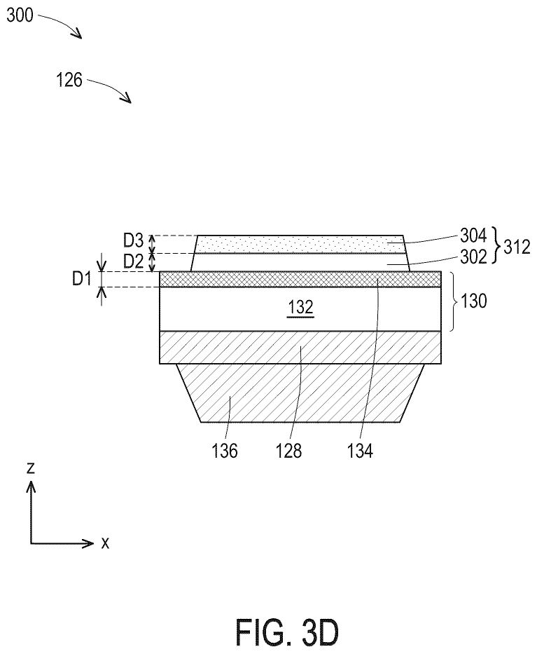

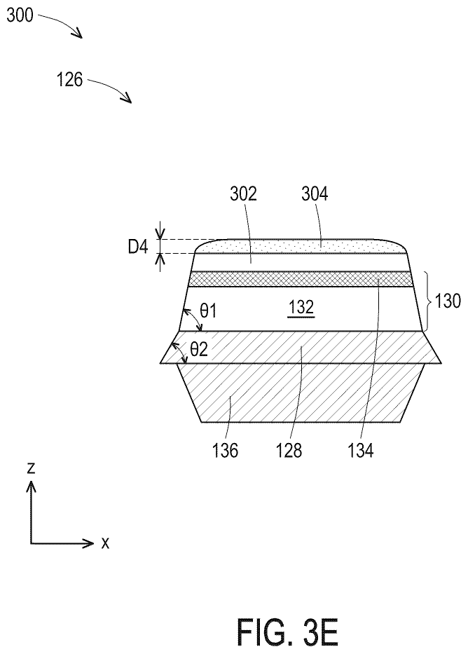

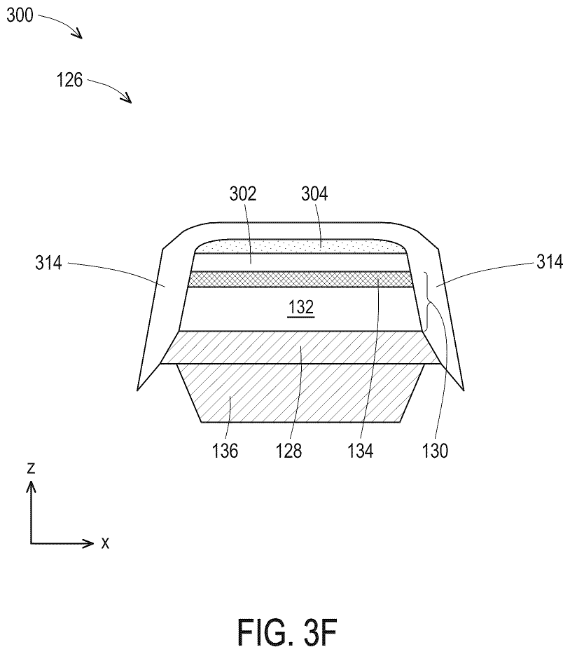

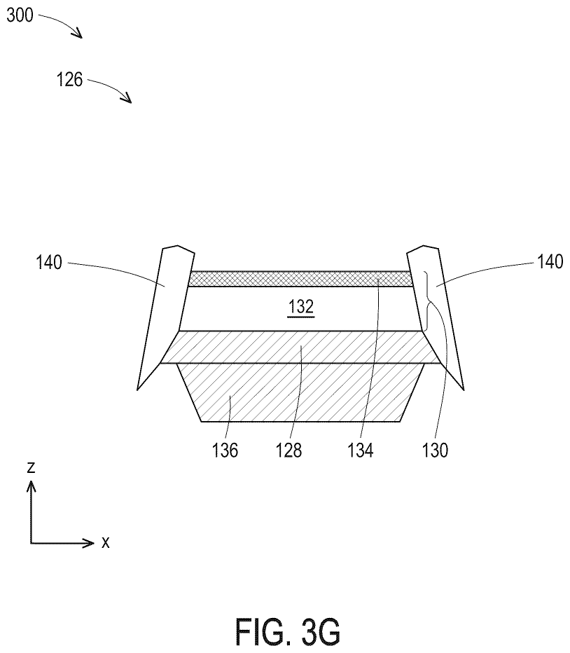

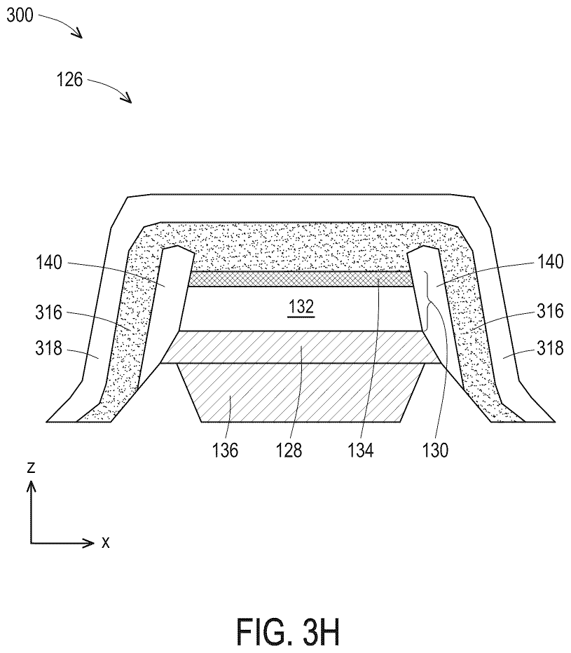

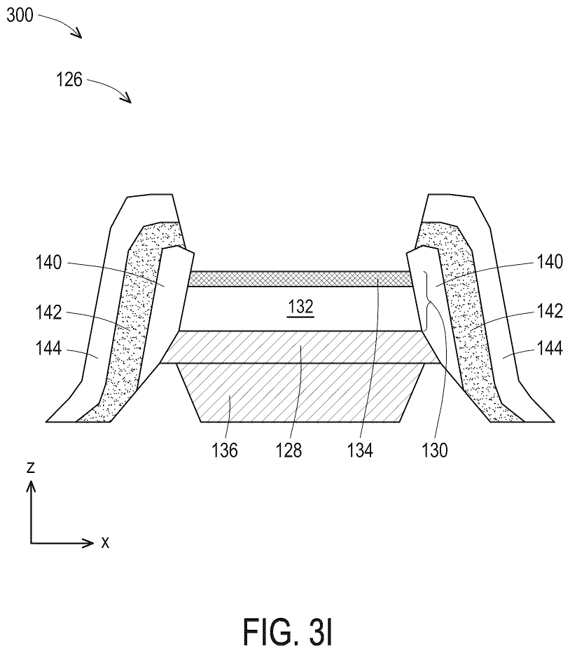

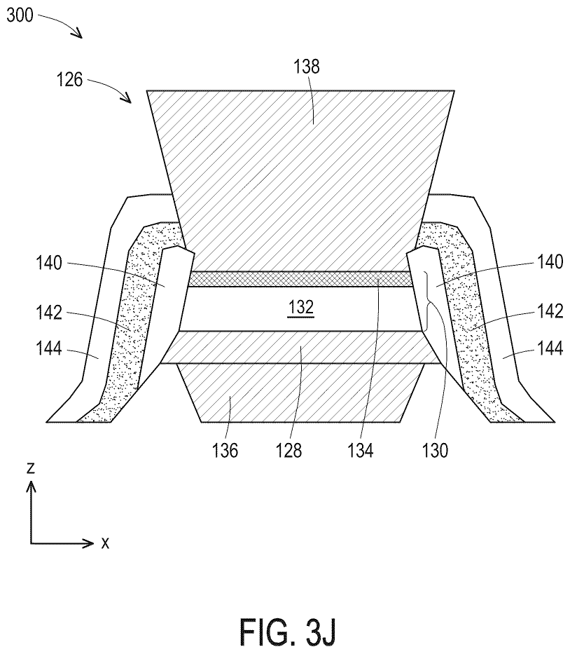

As shown in FIG. 2D, a second portion of the interconnect layer 104 of the semiconductor device 100 is formed above the first portion of the interconnect layer 104, including above and around the memory device 126. The second portion of the interconnect layer 104 may be formed in a similar manner as the first portion of the interconnect layer 104, as described in connection with FIG. 2C. The memory device 126 may be formed on and/or in one or more ILD layers 114 and/or one or more ESLs 116 in the interconnect layer 104. The memory device 126 may be formed such that the bottom electrode layer 128 of the memory device 126 lands on the bottom interconnect structure 136 in the interconnect layer 104, and the top interconnect structure 138 lands on the top layer 134 of the MTJ structure 130. An example process for forming the memory device 126 is illustrated and described in connection with FIGS. 3A-3J.

As shown in FIG. 2E, a remaining part of the second portion of the interconnect layer 104 of the semiconductor device 100 (e.g., layer 118e) is formed above layer 120d and above the memory device 126.

As indicated above, FIGS. 2A-2E are provided as an example. Other examples may differ from what is described with regard to FIGS. 2A-2E.

FIGS. 3A-3J are diagrams of an example implementation 300 described herein. Example implementation 300 may be an example process for forming the memory device 126 by using a dual dielectric layer HM structure to pattern the MTJ structure 130 and the bottom electrode layer 128. The memory device 126 formed using example implementation 300 may be included in a processor, a memory, or another type of electronic device.

As shown in FIG. 3A, in some implementations, the bottom electrode layer 128 is deposited on the bottom interconnect structure 136 and on a portion of a dielectric layer (e.g., ILD layer 114 or ESL 116) in which the bottom interconnect structure 136 may be formed. A deposition tool may be used to deposit the bottom electrode layer 128 using a CVD technique, a PVD technique, an ALD technique, an electroplating technique, and/or another suitable deposition technique. The material of the bottom electrode layer 128 may be deposited in one or more deposition operations. In some implementations, a seed layer is first deposited, and the material of the bottom electrode layer 128 is deposited on the seed layer. In some implementations, a planarization tool is used to perform a planarization operation (e.g., a CMP operation) to planarize the bottom electrode layer 128 after the bottom electrode layer 128 is deposited.

As further shown in FIG. 3A, a deposition tool may form the underlying layers 132 of the MTJ structure 130 over and/or on the top surface of the bottom electrode layer 128. In some implementations, a deposition tool forms the underlying layers 132 of the MTJ structure using a spin-coating technique, a CVD technique, a PVD technique, an ALD technique, and/or another deposition technique. A deposition tool may form the top layer 134 of the MTJ structure 130 over and/or on the top surface of an uppermost layer of the underlying layers 132. In some implementations, a deposition tool forms the top layer 134 using a CVD technique, a PVD technique, an ALD technique, an electroplating technique, and/or another suitable deposition technique. The material of the top layer 134 may be deposited in one or more deposition operations. In some implementations, a seed layer is first deposited, and the material of the top layer 134 is deposited on the seed layer. In some implementations, a planarization tool is used to perform a planarization operation (e.g., a CMP operation) to planarize the top layer 134 after the top layer 134 is deposited.

As shown in FIG. 3A, a deposition tool may form an HM structure including a first dielectric layer 302 over and/or on the top surface of the top layer 134 of the MTJ structure 130, and a second dielectric layer 304 over and/or on the first dielectric layer 302. In some implementations, a deposition tool forms the HM structure, including the first dielectric layer 302 and the second dielectric layer 304, using a spin-coating technique, a CVD technique, a PVD technique, an ALD technique, and/or another deposition technique. In some implementations, the first dielectric layer 302 includes tetraethyl orthosilicate (TEOS) and the second dielectric layer 304 includes carbon (C). In some implementations, the second dielectric layer 304 includes PVD-carbon (PVD-C) or tungsten (W)-doped carbon (C). The material of the first dielectric layer 302 is selected to promote adhesion between the material of the top layer 134 and the material of second dielectric layer 304, and other suitable dielectric materials for the first dielectric layer 302 may be used.

As further shown in FIG. 3A, the example process may be performed in connection with a bottom layer (BL) 306, a middle layer (ML) 308, and a photoresist (PR) mask 310, among other examples. For example, a deposition tool may form the BL 306, the ML 308, and the PR mask 310 over and/or on the top surface of the second dielectric layer 304. In some implementations, a deposition tool forms the BL 306, the ML 308, and the PR mask 310 using a spin-coating technique, a CVD technique, a PVD technique, an ALD technique, and/or another deposition technique.

As shown in FIG. 3B, the PR mask 310 may be patterned. In some implementations, an exposure tool exposes the PR mask 310 to a radiation source to form a pattern on the PR mask 310, and a developer tool develops and removes portions of the PR mask 310 to expose the pattern.

As shown in FIG. 3C, the ML 308 and the BL 306 may be patterned using the PR mask 310. For example, an etch tool may etch portions of the ML 308 and the BL 306. In some implementations, an etch tool uses a wet etch technique, a dry etch technique, a plasma-enhanced etch technique, and/or another type of etch technique to etch the portions of the ML 308 and the BL 306. As further shown in FIG. 3C, the PR mask 310 may be removed. For example, a photoresist removal tool may remove remaining portions of the PR mask 310 (e.g., using a chemical stripper, a plasma asher, and/or another technique) after an etch tool etches the ML 308 and the BL 306.

As shown in FIG. 3D, the HM structure 312 including the first dielectric layer 302 and the second dielectric layer 304 may be patterned (e.g., using the ML 308 and the BL 306). For example, an etch tool may etch portions of the first dielectric layer 302 and the second dielectric layer 304. In some implementations, an etch tool uses a halogen-based etch process (e.g., fluorine-based etch process, chlorine-based etch process, etc.) to etch the portions of the first dielectric layer 302 and the second dielectric layer 304. For example, the etch process may result in an angled profile for the HM structure 312 including the first dielectric layer 302 and the second dielectric layer 304, where the width of the HM structure 312 increases in the z-direction toward the top layer 134 of the MTJ structure 130. Additionally, due to its high etch resistivity to halogen-based etchants, the top layer 134 of the MTJ structure 130 may function as an ESL and thus prevent damage to the underlying layers 132 of the MTJ structure 130 while patterning the HM structure 312 including the first dielectric layer 302 and the second dielectric layer 304.

As shown in FIG. 3D, a thickness D1 (e.g., dimension in the z-direction) of the top layer 134 of the MTJ structure 130 may be included in a range of approximately 30 angstroms to approximately 100 angstroms. If the thickness D1 is smaller than approximately 30 angstroms, the top layer 134 may not function as an ESL, and may fail to prevent damage to the underlying layers 132 of the MTJ structure 130 when the first dielectric layer 302 and/or the second dielectric layer 304 are etched with a halogen-based etchant. If the thickness D1 is greater than approximately 100 angstroms, the working current of the memory device 126 may be higher, resulting in decreased electrical performance. However, other values and ranges are within the scope of the present disclosure.

A thickness D2 (e.g., dimension in the z-direction) of the first dielectric layer 302 is included in a range of approximately 50 angstroms to approximately 200 angstroms. If the thickness D2 is smaller than approximately 50 angstroms, when the MTJ structure 130 is patterned using the HM structure 312 including the first dielectric layer 302 and the second dielectric layer 304, the patterned MTJ structure 130 may have an overly tapered profile, which may reduce electrical performance of the memory device 126. In this case, “overly tapered” refers to too much of an increase in the width (e.g., dimension in the x-direction) of the MTJ structure 130 in the downward z-direction. In other words, a slope (e.g., steepness) of each side surface of the MTJ structure 130 may be too small (e.g., trending toward horizontal). If the thickness D2 is greater than approximately 150 angstroms, when the MTJ structure 130 is patterned using the HM structure 312 including the first dielectric layer 302 and the second dielectric layer 304, the profile of the patterned MTJ structure may be too close to vertical, which may reduce electrical performance of the memory device 126. In this case, “too close to vertical” refers to not enough of an increase in the width (e.g., dimension in the x-direction) of the MTJ structure 130 in the downward z-direction. In other words, a slope (e.g., steepness) of each side surface of the MTJ structure 130 may be too large (e.g., trending toward vertical). However, other values and ranges are within the scope of the present disclosure.

A thickness D3 (e.g., dimension in the z-direction) of the second dielectric layer 304 is included in a range of approximately 200 angstroms to approximately 350 angstroms. If the thickness D3 is smaller than approximately 200 angstroms, when the MTJ structure 130 is patterned using the HM structure 312 including the first dielectric layer 302 and the second dielectric layer 304, the patterned MTJ structure 130 may have an overly tapered profile, which may reduce electrical performance of the memory device 126. If the thickness D3 is greater than approximately 350 angstroms, when the MTJ structure 130 is patterned using the HM structure 312 including the first dielectric layer 302 and the second dielectric layer 304, the profile of the patterned MTJ structure may be too close to vertical, which may reduce electrical performance of the memory device 126. However, other values and ranges are within the scope of the present disclosure.

In some implementations, the thickness D3 of second dielectric layer 304 is greater than the thickness D2 of the first dielectric layer 302. For example, if the total thickness of the HM structure 312 (D2+D3) is approximately 400 angstroms, the thickness D2 of the first dielectric layer 302 may be approximately 150 angstroms, and the thickness D3 of the second dielectric layer 304 may be approximately 250 angstroms. However, other values are within the scope of the present disclosure.

As shown in FIG. 3E, portions of the MTJ structure 130 and of the bottom electrode layer 128 are removed in one or more etching processes, where the HM structure 312 is used as a mask that covers portions of the MTJ structure 130, and underlying portions of the bottom electrode layer 128. Exposed portions of the MTJ structure 130 and of the bottom electrode layer 128 that are not covered by the HM structure 312 are removed in the one or more etching processes. In some implementations, an etch tool uses a wet etch technique, a dry etch technique, a plasma-enhanced etch technique, and/or another type of etch technique to etch the exposed portions of the MTJ structure 130, and of the bottom electrode layer 128.

The resulting patterned MTJ structure 130 and patterned bottom electrode layer 128 each include angled side surfaces, such that the MTJ structure 130 and bottom electrode layer 128 each taper to a larger width (e.g., x-direction dimension) in the downward z-direction. The side surfaces of the patterned MTJ structure 130 are angled at an angle θ1 with respect to a bottom surface of the MTJ structure 130, and the side surfaces of the patterned bottom electrode layer 128 are angled at an angle θ2 with respect to a bottom surface of the bottom electrode layer 128. The angle θ1 may be larger than the angle θ2. In some implementations, the angle θ1 may be included in a range of approximately 80 degrees to approximately 88 degrees.

As shown in FIG. 3E, following patterning of the MTJ structure 130 and of the bottom electrode layer 128, the second dielectric layer 304 is reduced to a post-patterning thickness D4 (z-direction dimension), and also includes a top surface with a curved (e.g., arc-shaped) convex profile.

A post-patterning thickness D4 (e.g., dimension in the z-direction) of the second dielectric layer 304 is included in a range of approximately 50 angstroms to approximately 150 angstroms. If the post-patterning thickness D4 is smaller than approximately 50 angstroms, the patterned MTJ structure 130 may have an overly tapered profile (e.g., angle θ1 is too small), which may reduce electrical performance of the memory device 126. If the post-patterning thickness D4 is greater than approximately 150 angstroms, the profile of the patterned MTJ structure may be too close to vertical (e.g., angle θ1 is too large), which may reduce electrical performance of the memory device 126. However, other values and ranges are within the scope of the present disclosure.

As shown in FIG. 3F, a blanket spacer layer 314 for the formation of the first spacer layers 140 is conformally deposited on exposed side surfaces of the bottom electrode layer 128, on exposed side surfaces of the MTJ structure 130 including the top layer 134 and underlying layers 132, on exposed side surfaces of the first dielectric layer 302, and on exposed side and top surfaces of the second dielectric layer 304. The blanket spacer layer 314 may be further deposited on a dielectric layer adjacent to the bottom interconnect structure 136. A deposition tool may be used to deposit the blanket spacer layer 314 using an ALD technique, a CVD technique, and/or another suitable deposition technique.

As shown in FIG. 3G, an etch tool performs an etch process to remove a central portion of the blanket spacer layer 314 to form the first spacer layers 140. The etch process further removes the second dielectric layer 304, which is exposed by the removal of the central portion of the blanket spacer layer 314, and removes the first dielectric layer 302, which is exposed by the removal of the second dielectric layer 304. The removal of the first dielectric layer 302 exposes the top layer 134 of the MTJ structure 130. In some implementations, the etch tool uses a halogen-based etch process (e.g., fluorine-based etch process, chlorine-based etch process, etc.) to etch the central portion of the blanket spacer layer 314, and the underlying remaining portions of the first dielectric layer 302 and of the second dielectric layer 304. Due to its high etch resistivity to halogen-based etchants, the top layer 134 of the MTJ structure 130 may function as an ESL and thus prevent damage to the underlying layers 132 of the MTJ structure 130 during etching to remove the central portion of the blanket spacer layer 314, and the underlying remaining portions of the first dielectric layer 302 and of the second dielectric layer 304.

As shown in FIG. 3H, a blanket spacer layer 316 for the formation of the second spacer layers 142 is conformally deposited on exposed side and top surfaces of the first spacer layers, and on an exposed top surface of the top layer 134. The blanket spacer layer 314 may be further deposited on a dielectric layer adjacent to the bottom interconnect structure 136. In addition, a blanket spacer layer 318 for the formation of the third spacer layers 144 is conformally deposited on exposed surfaces of the blanket spacer layer 316. The blanket spacer layer 318 may be further deposited on a dielectric layer adjacent to the bottom interconnect structure 136. A deposition tool may be used to deposit the blanket spacer layer 316 and the blanket spacer layer 318 using an ALD technique, a CVD technique, and/or another suitable deposition technique.

As shown in FIG. 3I, an etch tool performs an etch process to remove central portions of the blanket spacer layers 316 and 318 to form the second and third spacer layers 142 and 144. The removal of the central portions of the blanket spacer layers 316 and 318 exposes the top layer 134 of the MTJ structure 130. In some implementations, the etch tool uses a halogen-based etch process (e.g., fluorine-based etch process, chlorine-based etch process, etc.) to etch the central portions of the blanket spacer layers 316 and 318. Due to its high etch resistivity to halogen-based etchants, the top layer 134 of the MTJ structure 130 may function as an ESL and thus prevent damage to the underlying layers 132 of the MTJ structure 130 during etching to remove the central portions of the blanket spacer layers 316 and 318.

As shown in FIG. 3J, a deposition tool is used to deposit the conductive material on the exposed top surface of the top layer 134 to form the top interconnect structure 138 on the top surface of the top layer 134. The top surface of the top layer 134 is substantially planar. The top interconnect structure 138 is formed between exposed side surfaces of the first, second, and third spacer layers 144, and on a portion of top surfaces of the first spacer layers 140. The top interconnect structure 138 is formed on and is in physical contact with the top layer 134 of the MTJ structure 130. The top layer 134 of the MTJ structure is a top electrode of the memory device 126.

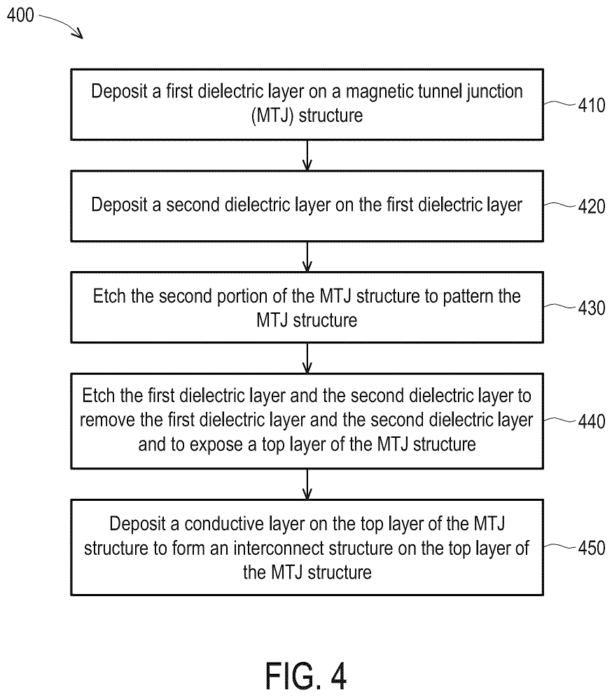

FIG. 4 is a flowchart of an example process 400 associated with a method of forming a semiconductor device. In some implementations, one or more process blocks of FIG. 4 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 4, process 400 may include depositing a first dielectric layer on an MTJ structure (block 410). For example, one or more semiconductor processing tools may be used to deposit a first dielectric layer (e.g., first dielectric layer 302) on an MTJ structure (e.g., MTJ structure 130), as described herein.

As further shown in FIG. 4, process 400 may include depositing a second dielectric layer on the first dielectric layer (block 420). For example, one or more semiconductor processing tools may be used to deposit a second dielectric layer (e.g., second dielectric layer 304) on the first dielectric layer, as described herein. In some implementations, the first dielectric layer and the second dielectric layer form a mask structure (e.g., HM structure 312) covering a first portion of the MTJ structure, and exposing a second portion of the MTJ structure.

As further shown in FIG. 4, process 400 may include etching the second portion of the MTJ structure to pattern the MTJ structure (block 430). For example, one or more semiconductor processing tools may be used to etch the second portion of the MTJ structure to pattern the MTJ structure, as described herein.

As further shown in FIG. 4, process 400 may include etching the first dielectric layer and the second dielectric layer to remove the first dielectric layer and the second dielectric layer and to expose a top layer of the MTJ structure (block 440). For example, one or more semiconductor processing tools may be used to etch the first dielectric layer and the second dielectric layer to remove the first dielectric layer and the second dielectric layer and to expose a top layer (e.g., top layer 134) of the MTJ structure, as described herein.

As further shown in FIG. 4, process 400 may include depositing a conductive layer on the top layer of the MTJ structure to form an interconnect structure on the top layer of the MTJ structure (block 450). For example, one or more semiconductor processing tools may be used to deposit a conductive layer on the top layer of the MTJ structure to form an interconnect structure (top interconnect structure 138) on the top layer of the MTJ structure, as described herein.

Process 400 may include additional implementations, such as any single implementation or any combination of implementations described below and/or in connection with one or more other processes described elsewhere herein.

In a first implementation, the top layer of the MTJ structure includes a conductive material.

In a second implementation, alone or in combination with the first implementation, the conductive material includes one of ruthenium (Ru), platinum (Pt), gold (Au), nickel (Ni), or chromium (Cr).

In a third implementation, alone or in combination with one or more of the first and second implementations, process 400 includes depositing, prior to etching the first dielectric layer and the second dielectric layer, a spacer layer (e.g., blanket spacer layer 314) on the patterned MTJ structure, on the first dielectric layer, and on the second dielectric layer.

In a fourth implementation, alone or in combination with one or more of the first through third implementations, process 400 includes etching, prior to etching the first dielectric layer and the second dielectric layer, a portion of the spacer layer formed on a top surface of the second dielectric layer to remove the portion of the spacer layer and to expose the top surface of the second dielectric layer.

In a fifth implementation, alone or in combination with one or more of the first through fourth implementations, an unetched portion of the spacer layer (e.g., first spacer layers 140) remains on side surfaces of the patterned MTJ structure.

In a sixth implementation, alone or in combination with one or more of the first through fifth implementations, etching the first dielectric layer and the second dielectric layer, and etching of the portion of the spacer layer, are performed with a halogen-based etchant.

In a seventh implementation, alone or in combination with one or more of the first through sixth implementations, the second dielectric layer includes carbon.

In an eighth implementation, alone or in combination with one or more of the first through seventh implementations, the first dielectric layer includes tetraethyl orthosilicate (TEOS).

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

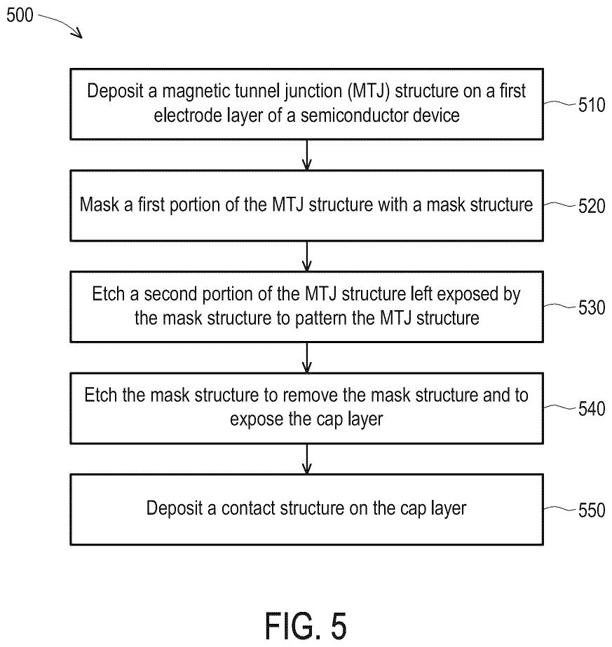

FIG. 5 is a flowchart of an example process 500 associated with a method of forming a semiconductor device. In some implementations, one or more process blocks of FIG. 5 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 5, process 500 may include depositing a magnetic tunnel junction (MTJ) structure on a first electrode layer of a semiconductor device (block 510). For example, one or more semiconductor processing tools may be used to deposit a magnetic tunnel junction (MTJ) structure (e.g., MTJ structure 130) on a first electrode layer (e.g., bottom electrode layer 128) of a semiconductor device (e.g., memory device 126), as described herein. In some implementations, the MTJ structure includes a plurality of layers (e.g., underlying layers 132 and top layers 134). In some implementations, a cap layer (e.g., top layer 134) of the plurality of layers includes a conductive material.

As further shown in FIG. 5, process 500 may include masking a first portion of the MTJ structure with a mask structure (block 520). For example, one or more semiconductor processing tools may be used to mask a first portion of the MTJ structure with a mask structure (e.g., HM structure 312), as described herein. In some implementations, the mask structure includes a plurality of dielectric layers (e.g., first dielectric layer 302 and second dielectric layer 304) in a stacked arrangement.

As further shown in FIG. 5, process 500 may include etching a second portion of the MTJ structure left exposed by the mask structure to pattern the MTJ structure (block 530). For example, one or more semiconductor processing tools may be used to etch a second portion of the MTJ structure left exposed by the mask structure to pattern the MTJ structure, as described herein.

As further shown in FIG. 5, process 500 may include etching the mask structure to remove the mask structure and to expose the cap layer (block 540). For example, one or more semiconductor processing tools may be used to etch the mask structure to remove the mask structure and to expose the cap layer, as described herein.

As further shown in FIG. 5, process 500 may include depositing a contact structure on the cap layer (block 550). For example, one or more semiconductor processing tools may be used to deposit a contact structure (e.g., top interconnect structure 138) on the cap layer, as described herein. In some implementations, the cap layer is a second electrode layer of the semiconductor device.

Process 500 may include additional implementations, such as any single implementation or any combination of implementations described below and/or in connection with one or more other processes described elsewhere herein.

In a first implementation, the mask structure is etched with an etchant that selectively etches the mask structure with respect to the cap layer.

In a second implementation, alone or in combination with the first implementation, an upper dielectric layer (e.g., second dielectric layer 304) of the plurality of dielectric layers in the stacked arrangement includes carbon.

In a third implementation, alone or in combination with one or more of the first and second implementations, before the second portion of the MTJ structure is etched, a thickness (e.g., thickness D3) of an upper dielectric layer (e.g., second dielectric layer 304) of the plurality of dielectric layers in the stacked arrangement is greater than a thickness (e.g., thickness D2) of a lower dielectric layer (e.g., first dielectric layer 302) of the plurality of dielectric layers in the stacked arrangement.

In a fourth implementation, alone or in combination with one or more of the first, second, and third implementations, after the second portion of the MTJ structure is etched, a thickness (e.g., thickness D4) of an upper dielectric layer (e.g., second dielectric layer 304) of the plurality of dielectric layers in the stacked arrangement is included in a range of approximately 50 angstroms to approximately 150 angstroms.

In a fifth implementation, alone or in combination with one or more of the first, second, third, and fourth implementations, process 500 includes depositing, prior to etching the mask structure, a spacer layer (e.g., blanket spacer layer 314) around the patterned MTJ structure and around the mask structure, where the spacer layer covers side surfaces of the patterned MTJ structure, and a top surface of the mask structure.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, an HM structure includes two dielectric layers, where the dual dielectric layer HM structure is used as a mask to pattern an MTJ structure of a memory device (e.g., MRAM device), and to pattern a bottom electrode layer of the memory device. The dual dielectric layer HM structure is removed in a halogen-based etch process, and a top metal layer of the MTJ structure is used as the top electrode of the memory device. The top metal layer of the MTJ structure may be formed from a material that is resistant to halogen-based etchants. The dual dielectric layer HM structure has a lower height than a dielectric and metal layer HM structure where the metal layer is formed into a top electrode, resulting in a lower aspect ratio (e.g., height-to-width ratio) than the dielectric and metal layer HM structure. Due to the lower aspect ratio and the non-metal composition of the dual dielectric layer HM structure, generation of metal by-products during patterning of the MTJ and bottom electrode layers may be reduced and/or prevented, thereby preventing shorts between electrodes of adjacent memory devices and/or between top and bottom electrodes of the same memory device. As a result, memory device performance may be increased and malfunction incidents may be decreased.

As described in greater detail above, some implementations described herein provide a method. The method includes depositing a first dielectric layer on a magnetic tunnel junction (MTJ) structure. The method includes depositing a second dielectric layer on the first dielectric layer, where the first dielectric layer and the second dielectric layer form a mask structure covering a first portion of the MTJ structure, and exposing a second portion of the MTJ structure. The method includes etching the second portion of the MTJ structure to pattern the MTJ structure. The method includes etching the first dielectric layer and the second dielectric layer to remove the first dielectric layer and the second dielectric layer and to expose a top layer of the MTJ structure. The method includes depositing a conductive layer on the top layer of the MTJ structure to form an interconnect structure on the top layer of the MTJ structure.

As described in greater detail above, some implementations described herein provide a method. The method includes depositing a magnetic tunnel junction (MTJ) structure on a first electrode layer of a semiconductor device, where the MTJ structure includes a plurality of layers, and where a cap layer of the plurality of layers includes a conductive material. The method includes masking a first portion of the MTJ structure with a mask structure, where the mask structure includes a plurality of dielectric layers in a stacked arrangement. The method includes etching a second portion of the MTJ structure left exposed by the mask structure to pattern the MTJ structure. The method includes etching the mask structure to remove the mask structure and to expose the cap layer. The method includes depositing a contact structure on the cap layer, where the cap layer is a second electrode layer of the semiconductor device.

As described in greater detail above, some implementations described herein provide a semiconductor structure. The semiconductor structure includes a bottom electrode of the semiconductor structure. The semiconductor structure includes a magnetic tunnel junction (MTJ) structure on the bottom electrode, where the MTJ structure includes a plurality of layers, and where a top layer of the plurality of layers is a top electrode of the semiconductor structure. The semiconductor structure includes an interconnect structure disposed on and in contact with the top layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a first dielectric layer on a magnetic tunnel junction (MTJ) structure;
depositing a second dielectric layer on the first dielectric layer,
wherein the first dielectric layer and the second dielectric layer form a mask structure covering a first portion of the MTJ structure, and exposing a second portion of the MTJ structure;
etching the second portion of the MTJ structure to pattern the MTJ structure;
etching the first dielectric layer and the second dielectric layer to remove the first dielectric layer and the second dielectric layer and to expose a top layer of the MTJ structure; and
depositing a conductive layer on the top layer of the MTJ structure to form an interconnect structure on the top layer of the MTJ structure.

2. The method of claim 1, wherein the top layer of the MTJ structure comprises a conductive material.

3. The method of claim 2, wherein the conductive material comprises one of ruthenium (Ru), platinum (Pt), gold (Au), nickel (Ni), or chromium (Cr).

4. The method of claim 1, further comprising depositing, prior to etching the first dielectric layer and the second dielectric layer, a spacer layer on the patterned MTJ structure, on the first dielectric layer, and on the second dielectric layer.

5. The method of claim 4, further comprising etching, prior to etching the first dielectric layer and the second dielectric layer, a portion of the spacer layer formed on a top surface of the second dielectric layer to remove the portion of the spacer layer and to expose the top surface of the second dielectric layer.

6. The method of claim 5, wherein an unetched portion of the spacer layer remains on side surfaces of the patterned MTJ structure.

7. The method of claim 5, wherein etching the first dielectric layer and the second dielectric layer, and etching of the portion of the spacer layer are performed with a halogen-based etchant.

8. The method of claim 1, wherein the second dielectric layer comprises carbon.

9. The method of claim 8, wherein the first dielectric layer comprises tetraethyl orthosilicate (TEOS).

10. A method, comprising:
depositing a magnetic tunnel junction (MTJ) structure on a first electrode layer of a semiconductor device,
wherein the MTJ structure comprises a plurality of layers, and
wherein a cap layer of the plurality of layers comprises a conductive material;
masking a first portion of the MTJ structure with a mask structure,
wherein the mask structure comprises a plurality of dielectric layers in a stacked arrangement;
etching a second portion of the MTJ structure left exposed by the mask structure to pattern the MTJ structure;
etching the mask structure to remove the mask structure and to expose the cap layer; and
depositing a contact structure on the cap layer,
wherein the cap layer is a second electrode layer of the semiconductor device.

11. The method of claim 10, wherein the mask structure is etched with an etchant that selectively etches the mask structure with respect to the cap layer.

12. The method of claim 10, wherein an upper dielectric layer of the plurality of dielectric layers in the stacked arrangement comprises carbon.

13. The method of claim 10, wherein, before the second portion of the MTJ structure is etched, a thickness of an upper dielectric layer of the plurality of dielectric layers in the stacked arrangement is greater than a thickness of a lower dielectric layer of the plurality of dielectric layers in the stacked arrangement.

14. The method of claim 10, wherein, after the second portion of the MTJ structure is etched, a thickness of an upper dielectric layer of the plurality of dielectric layers in the stacked arrangement is included in a range of approximately 50 angstroms to approximately 150 angstroms.

15. The method of claim 10, further comprising:
depositing, prior to etching the mask structure, a spacer layer around the patterned MTJ structure and around the mask structure,
wherein the spacer layer covers side surfaces of the patterned MTJ structure, and a top surface of the mask structure.

16. A semiconductor structure, comprising:
a bottom electrode of the semiconductor structure;
a magnetic tunnel junction (MTJ) structure on the bottom electrode,
wherein the MTJ structure comprises a plurality of layers, and
wherein a top layer of the plurality of layers is a top electrode of the semiconductor structure; and
an interconnect structure disposed on and in contact with the top layer.

17. The semiconductor structure of claim 16, wherein a thickness of the top layer is included in a range of approximately 30 angstroms to approximately 100 angstroms.

18. The semiconductor structure of claim 16, wherein a material of the top layer comprises one of ruthenium (Ru), platinum (Pt), gold (Au), nickel (Ni), or chromium (Cr).

19. The semiconductor structure of claim 16, wherein the interconnect structure is directly disposed on a top surface of the top layer.

20. The semiconductor structure of claim 19, wherein the top surface of the top layer is substantially planar.
